(19) United States
(12) Patent Application Publication
(10) Pub. No.: US 2010/0328338 A1
(43) Pub. Date: Dec. 30, 2010

(54) BRIGHTNESS CONTROLLABLE LED ILLUMINATION DEVICE WITH TACTILE SENSOR SENSING INTENSITY OF FORCE OR INTENSITY OF PRESSURE, FLAT PANEL DISPLAY HAVING THE SAME, MOBILE TERMINAL KEYPAD HAVING THE SAME, ROBOT EYE AND ROBOT NOSE HAVING THE SAME, AND METHOD OF OPERATING THE SAME

(75) Inventors: Jong Ho Kim, Daejeon (KR); Min Seok Kim, Daejeon (KR); Yon-Kyu Park, Daejeon (KR); Dae Im Kang, Daejeon (KR)

Correspondence Address: AKERMAN SENTERFITT, P.O. BOX 3188, WEST PALM BEACH, FL, 33402-3188, US

(73) Assignee: Korea Research Institute of Standards and Science, Daejeon (KR)

(21) Appl. No.: 12/621,871

(22) Filed: Nov. 19, 2009

(30) Foreign Application Priority Data
Jun. 24, 2009 (KR) 10-2009-0056304

(51) Int. Cl. G09G 5/02; G08B 21/00; H03M 11/00

(52) U.S. Cl. 345/589; 340/665; 341/22

(57) ABSTRACT

Disclosed herein is a brightness controllable LED illumination device using a tactile sensor sensing the intensity of force or the intensity of pressure. The brightness controllable LED illumination device includes at least one LED emitting light based on electric field formed between first and second electrodes; a tactile sensor sensing the intensity of force or pressure applied by a predetermined contact object and generating an output signal corresponding to the sensed intensity; and a controller connected to the tactile sensor and adjusting a variation in the electric field based on the output signal of the tactile sensor to control the brightness of the light emitted from the at least one LED.

### BACKGROUND OF THE INVENTION

1. Field of the Invention

The present invention relates to an illumination device capable of controlling the brightness of light emitted from a light-emitting diode (LED). More specifically, the invention relates to a brightness controllable LED illumination device with a tactile sensor sensing the intensity of force or the intensity of pressure, a flat panel display having the same, a mobile terminal keypad having the same, a robot eye and robot nose having the same, and a method of operating the same.

2. Background of the Related Art

An LED is a semiconductor device that emits light when a voltage is applied thereto using the property of a compound semiconductor and has advantages of long lifetime, chemical stability and high durability. The LED has optical efficiency higher than those of a glow lamp and a fluorescent lamp, generates various colors and is brightness controllable, and thus the LED is widely used for various purposes including electric sign boards, traffic signal, home appliance displays, mobile phones, etc. Furthermore, the development of LED is carried out in various manners such that the LED is applied to indirect lighting, exterior lighting, architectural lighting, automobile lighting and back lighting of large-size liquid crystal displays with the development of semiconductor technology.

FIG. 1 is a conceptional view showing the principle of an LED. Referring to FIG. 1, the LED, a kind of p-n junction diode, is a semiconductor device using electroluminescence that emits monochromatic light when a forward voltage is applied to the LED, that is, when a voltage is applied in a direction from an anode 3 to a cathode 4. When the forward voltage is applied, electrons of an electron layer 2 and holes of a hole layer 1 are combined to generate energy corresponding to a energy gap between the conduction band and the valance band. This energy is radiated in the form of light, and thus the semiconductor device becomes a light-emitting diode.

FIG. 2 is a perspective view of a conventional LED 10. Referring to FIG. 2, the conventional LED 10 includes a first electrode (anode) 11 and a second electrode (cathode) 12 which are electrically connected to a power supply (not shown), an LED chip 13 mounted on the second electrode 12, a conductive wire 14 electrically connecting the first electrode 11 to the LED chip 13, and a sealing part 15 sealing up the LED chip 13 and the conductive wire 14. When a voltage is applied to the LED 10 through the first and second electrodes 11 and 12 exposed to the outside of the LED 10, light is emitted from the LED 10 according to energy generated as electrons move.

There are LEDs in various forms, which are applied to a variety of devices. Particularly, a technique of controlling the brightness of an LED generally uses a method of operating a rotary knob (not shown). Specifically, ON/OFF of LED is controlled according to rotation of the rotary knob and the brightness of LED is also controlled by rotating the rotary knob while ON/OFF of LED is controlled. Further, various techniques of arranging LEDs and emission sequence are used for color LED displays. For example, there is a technique of constructing pixels in such a manner that each pixel includes a red sub-pixel, a green sub-pixel and a blue sub-pixel and achieving time division display according to combination turn-on/turn-off of sub-pixels to express multiple colors.

However, an LED operating method which responds to and is sensitive to users are being developed and a brightness controlling device capable of controlling brightness instantly and intuitively through a simple and intuitive method is being studied. Meantime, a mobile terminal such as a cellular phone becomes a necessity and is developed such that the mobile terminal provides various interfaces to stimulate human emotion. For example, a mobile terminal keypad can instantly vary its brightness according to the surrounding brightness and continuously perform brightness change in response to a user's operation to stimulate the emotion of the user. Accordingly, improved devices for controlling the brightness of LED are continuously studied and developed in order to utilize conventional brightness controlling methods.

### SUMMARY OF THE INVENTION

Accordingly, the present invention has been made in view of the above-mentioned problems occurring in the prior art, and it is a primary object of the present invention to provide a brightness controllable LED illumination device based on a tactile sensor sensing the intensity of force or the intensity of pressure, which is applied to a mobile terminal display illuminating device, a keypad illuminating device and an illuminating device for advertisement, a flat panel display having the same, a mobile terminal keypad having the same, and a method of operating the same.

It is a second object of the present invention to provide a brightness controllable LED illumination device with a tactile sensor sensing the intensity of force or the intensity of pressure, which provides analog feeling and convenience for advertisement lighting, a flat panel display having the same, a mobile terminal keypad having the same, and a method of operating the same.

It is a third object of the present invention to provide a brightness controllable LED illumination device with a tactile sensor sensing the intensity of force or the intensity of pressure, which is able to save energy through appropriate brightness control, a flat panel display having the same, a mobile terminal keypad having the same, and a method of operating the same.

To accomplish the above objects of the present invention, according to the present invention, there is provided a brightness controllable LED illumination device with a tactile sensor sensing the intensity of force or the intensity of pressure, which includes at least one LED emitting light based on electric field formed between first and second electrodes; a tactile sensor sensing the intensity of force or pressure applied by a predetermined contact object and generating an output signal corresponding to the sensed intensity; and a controller connected to the tactile sensor and adjusting a variation in the electric field based on the output signal of the tactile sensor to control the brightness of the light emitted from the at least one LED.

The brightness controllable LED illumination device with a tactile sensor sensing the intensity of force or the intensity of pressure may further include a display panel illuminated by the light emitted from the at least one LED.

Each of the at least one LED may generate a single light beam corresponding to one of red, green and blue, and the at least one LED may correspond to a plurality of LED groups each of which includes three LEDs.

Each of the at least one LED may generate a single light beam corresponding to one of complementary colors, and the at least one LED may correspond to a plurality of LED groups each of which includes two LEDs.

Each of the at least one LED may include at least one phosphor.

Each of the at least one LED may emit blue light and the phosphor may be yellow phosphor.

The output signal may be proportional to the intensity of force or pressure applied by the contact object.

The tactile sensor may use contact resistance or piezoresistance.

The tactile sensor may use capacitance.

The tactile sensor may be a piezoelectric tactile sensor.

The controller may include a potentiometer having resistance that is varied based on the output signal of the tactile sensor to control the electric field variation based on the resistance variation.

To accomplish the above objects of the present invention, according to the present invention, there is provided a plat panel display comprising the LED illumination device.

To accomplish the above objects of the present invention, there is provided a mobile terminal keypad device comprising the LED illumination device.

To accomplish the above objects of the present invention, there is provided a robot eye and nose comprising the LED illumination device.

To accomplish the above objects of the present invention, there is provided a method of controlling the brightness of a brightness controllable LED illumination device with a tactile sensor sensing the intensity of force or the intensity of pressure, which includes a first variation step S110 in which one of contact resistance of a tactile sensor, piezoresistance of a tactile sensor, capacitance of a tactile sensor and piezoelectric voltage of a tactile sensor, which corresponds to the intensity of force or pressure applied by a predetermined contact object, is varied; a second variation step S120 in which the output signal of the tactile sensor is varied based on the variation in the first variation step; a third variation step S130 in which a controller varies electric field between first and second electrodes of an LED based on the output signal variation; and a brightness control step S140 in which the brightness of light emitted from the LED is controlled based on the electric field variation.

The method of controlling the brightness of a brightness controllable LED illumination device with a tactile sensor sensing the intensity of force or the intensity of pressure may further include a step S125 in which resistance of a potentiometer is varied based on the output signal of the tactile sensor between the second variation step S120 and the third variation step S130.

The brightness control step S140 may include the steps of controlling the brightnesses of lights emitted from LEDs emitting red, green and blue lights; and controlling the brightnesses of the red, green and blue lights to generate light in a color corresponding to combination of red, green and blue.

The present invention can continuously control the brightness of an LED illumination device based on the intensity of force or pressure applied thereto, which is distinguished from a conventional illumination device employing LEDs, which controls brightness using a rotary knob.

Furthermore, the continuous brightness control based on the intensity of force can provide analog feeling and convenience to users when the users use displays and keypads of various terminals and advertisement illuminating devices to which the present invention is applied.

Moreover, appropriate brightness control saves energy.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a conceptional view showing the principle of a light-emitting diode (LED);

FIG. 2 is a perspective view of a conventional LED;

FIG. 3 shows a configuration of a brightness controllable LED illumination device according to the present invention;

FIG. 4 is a cross-sectional view of a contact resistance tactile sensor included in the brightness controllable LED illumination device according to an embodiment of the present invention;

FIG. 5 is an exploded perspective view showing a backlight unit of a cellular phone display, which is combined with a tactile sensor, according to an embodiment of the present invention;

FIG. 6 is an exploded perspective view showing a cellular phone keypad illuminating device combined with a tactile sensor according to an embodiment of the present invention;

FIG. 7 is an exploded perspective view of a brightness controllable advertisement illuminating device using a tactile sensor according to an embodiment of the present invention;

FIG. 8 shows a robot including a brightness controllable robot eye and robot nose using a tactile sensor according to an embodiment of the present invention;

FIG. 9 is a flowchart showing a method of controlling the brightness of the brightness controllable LED illumination device according to an embodiment of the present invention; and

FIG. 10 is a flowchart showing a method of controlling the brightnesses of LEDs respectively emitting red, green and blue lights to generate various colors according to an embodiment of the present invention.

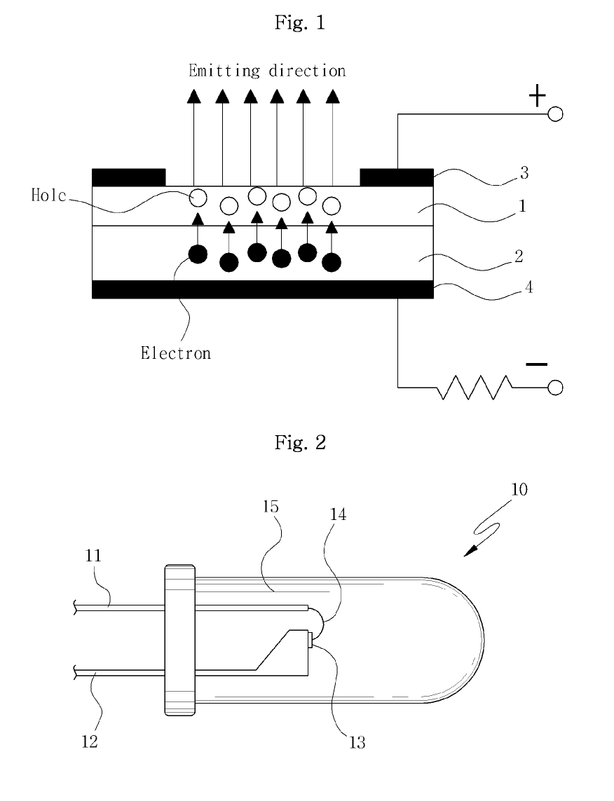

### DETAILED DESCRIPTION OF THE PREFERRED EMBODIMENT

### Embodiment

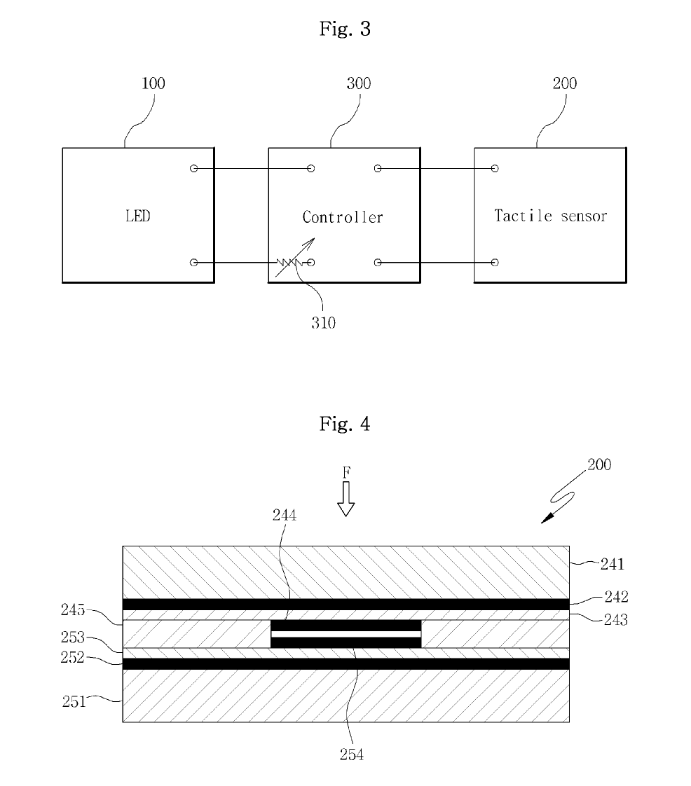

FIG. 3 shows a configuration of a brightness controllable LED illumination device according to an embodiment of the present invention. Referring to FIG. 3, the brightness controllable LED illumination device may include at least one LED 100, a tactile sensor 200 and a controller 300. The controller 300 may include a potentiometer 310 configured in the form of a variable resistor.

The LED 100 emits monochrome light, in general. White light used for lighting is obtained through a method of coating a fluorescent material on an LED chip emitting blue light, a method of coating a fluorescent material on an LED chip emitting purple light, a method of combining two LED chips, or a method of combining three LED chips. In the current embodiment of the invention, LEDs manufactured through the aforementioned four methods may be used.

A white LED that can be used in the current embodiment of the invention will now be roughly explained. Firstly, the white LED employs a blue LED as a light source as a high-brightness blue LED is commercialized and uses a fluorescent material emitting yellow (560 nm) of YAG (Yttium Aluminum Garnet) to produce excited light. This is a simple structure having a single chip and two terminals. Secondly, the white LED employs a purple LED as an excited light source and uses multi-layered fluorescent materials in red, green and blue to generate excited light. Thirdly, red, green and blue LED chips are combined to produce a white LED. This is suitable for special illumination that requires various representations according to control of brightnesses of LEDs through circuit configuration rather than for constructing a white LED. Fourthly, two LEDs respectively emitting lights in complementary colors are combined to achieve a white LED. For example, orange color and bluish green color can be mixed with each other in the ratio of 4:1 to obtain white.

The tactile sensor 200 can sense the intensity of force or pressure applied by a predetermined contact object (for example, a finger). Although the contact resistance tactile sensor 200 is used in the current embodiment of the invention, a capacitance tactile sensor (not shown) and a piezoelectric tactile sensor (not shown) may be used. In addition, any sensor capable of sensing the intensity of force or the intensity of pressure can be used in the present invention. The tactile sensor 200 according to the current embodiment of the invention will be described later in detail with reference to FIG. 4.

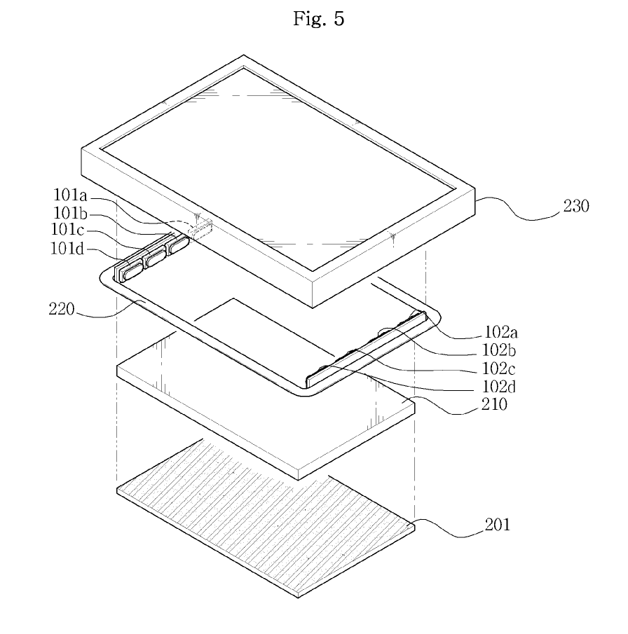

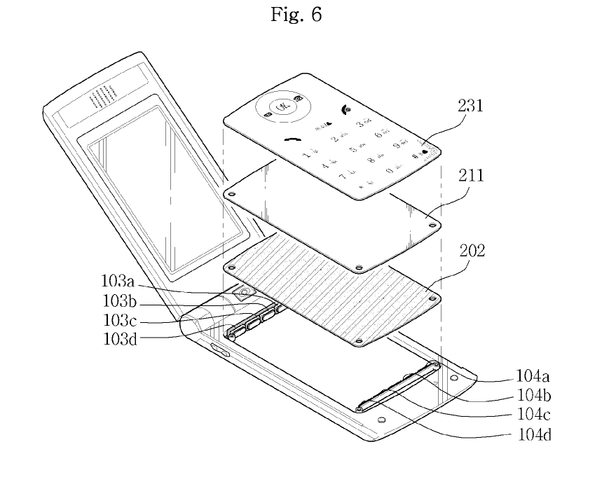

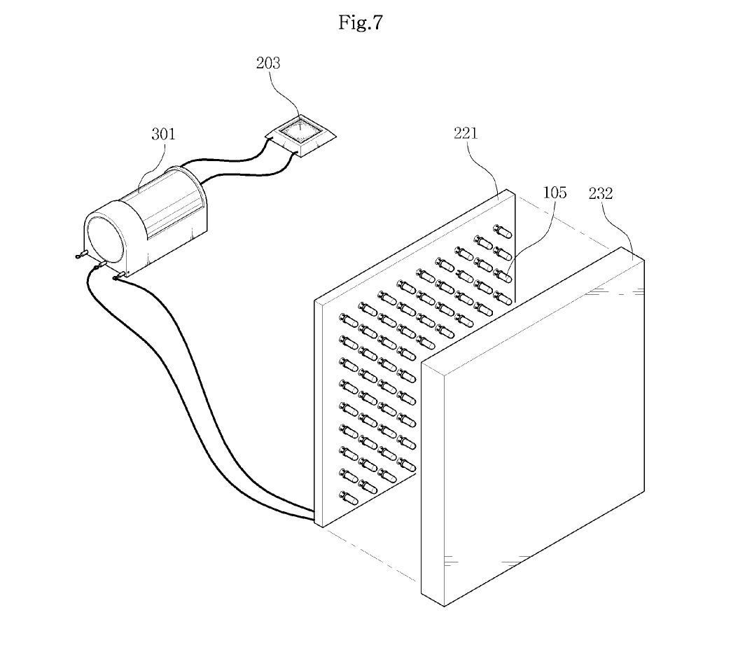

The tactile sensor 200 can be attached to a display panel illuminating device, as shown in FIG. 5, and attached in the form of a sheet to a cellular phone keypad, as shown in FIG. 6. Further, the tactile sensor 200 can be configured in the form of a touch pad to receive the intensity of force or the intensity of pressure for controlling the brightness of an advertisement illuminating device, as shown in FIG. 7.

The controller 300 receives the output signal of the tactile sensor 200 when contact force or pressure is directly applied to the tactile sensor 200. Further, the controller 300 can adjust current flowing through the LED 100 using a variable resistor 310 (for example, potentiometer) to control the brightness of the LED 100 in proportion to the output signal of the tactile sensor 200 based on the output signal of the tactile sensor 200. In addition, the controller 300 may include a central processing unit that controls input and output of the tactile sensor 200 and the LED 100 between the tactile sensor 200 and the LED 100.

The potentiometer 310 varies its resistance and adjusts current flowing through the LED 100 based on a variation in the output of the tactile sensor 200, such as a potential variation, as described above with reference to the emission principle of the LED 100.

FIG. 4 is a cross-sectional view of the contact resistance tactile sensor 200 according to an embodiment of the present invention. Referring to FIG. 4, the tactile sensor 200 includes an upper plate manufactured in such a manner that a coating film 242 and a metal layer 243 are sequentially formed on a polymer film 241 having a predetermined thickness and a resistor 244 is formed on the metal layer 243, and a lower plate manufactured in such a manner that a coating film 252 and a metal layer 253 are sequentially formed on a polymer film 251 having a predetermined thickness and a resistor 254 is formed on the metal layer 253. The upper plate and the lower plate are bonded to each other having a spacer 255 interposed between the resistor 244 of the upper plate and the resistor 254 of the lower plate.

FIG. 5 is an exploded perspective view showing a backlight unit of a cellular phone display, which is combined with a tactile sensor 201 according to an embodiment of the present invention. An LED display having LEDs arranged therein can be used as not only a display device but also a backlight of a liquid crystal display (LCD). A general cellular phone backlight unit has a rectangular two-dimensional shape and includes a lens sheet, a dispersion sheet, a light guide, and a reflection sheet. FIG. 5 illustrates only LED lamps 101a, 101b, 101c, 101d, 1021, 102b, 102c and 102d, a supporting frame 220 supporting the LED lamps 101a, 101b, 101c, 101d, 1021, 102b, 102c and 102d and a light guide 210 among constituent elements of the backlight unit and does not show a controller for clarifying the present invention. As shown in FIG. 5, the tactile sensor 201 is arranged under the light guide 210 and senses contact force applied to a display panel 230. Lights emitted from the LED lamps 101a, 101b, 101c, 101d, 1021, 102b, 102c and 102d, which are paired and are arranged on both sides of the light guide 210, are controlled according to a variation in the intensity of force or the intensity of pressure.

FIG. 6 is an exploded perspective view showing a cellular phone keypad illuminating device, which is combined with a tactile sensor 202, according to an embodiment of the present invention. The cellular phone keypad illuminating device including the tactile sensor 202 has a configuration similar to that of the backlight unit shown in FIG. 5. That is, the cellular phone keypad illuminating device includes a keypad cover 231, a light guide 211 having a reflecting pattern (not shown) and the tactile sensor 202, which are'located under the keypad cover 231, and a plurality of LED lamps 103a, 103b, 103c, 103d, 104a, 104b, 104c and 104d arranged on both sides of the light guide 211. Here, the light guide 211 guides lights emitted from the LED lamps 103a, 103b, 103c, 103d, 104a, 104b, 104c and 104d to disperse the lights to the front side of the keypad.

When contact force or pressure is applied to the keypad cover 231, the tactile sensor 202 outputs an output signal in proportion to the intensity of the contact force or pressure, and thus the brightness of the LED lamps 103a, 103b, 103c, 103d, 104a, 104b, 104c and 104d is controlled through a controller (not shown).

FIG. 7 is an exploded perspective view showing a brightness controllable advertisement illuminating device using a tactile sensor 203 according to an embodiment of the present invention. As shown in FIG. 7, the brightness controllable advertisement illuminating device may include a circuit board 221, a plurality of LED lamps 105 functioning as a light source, a transparent or semi-transparent protective cover 232 arranged in front of the LED lamps 105, a controller 301 connected to the circuit board 221, and the tactile sensor 203 in the form of a touch pad, which transmits an output signal in proportion to the intensity of force to the controller 301. Here, the controller may include a potentiometer having variable resistance.

The tactile sensor 203 may be a touch pad of laptop or a switching device in the form of a touch pad. The circuit board 221 has a circuit capable of displaying various advertisements, which is mounted on the circuit board 221, to determine whether the LED lamps 105 emit lights. The controller 301 receives the output signal of the tactile sensor 203, which corresponds to the intensity of force or pressure applied to the tactile sensor 203, and controls the brightness of the LED lamps 105 based on the output signal.

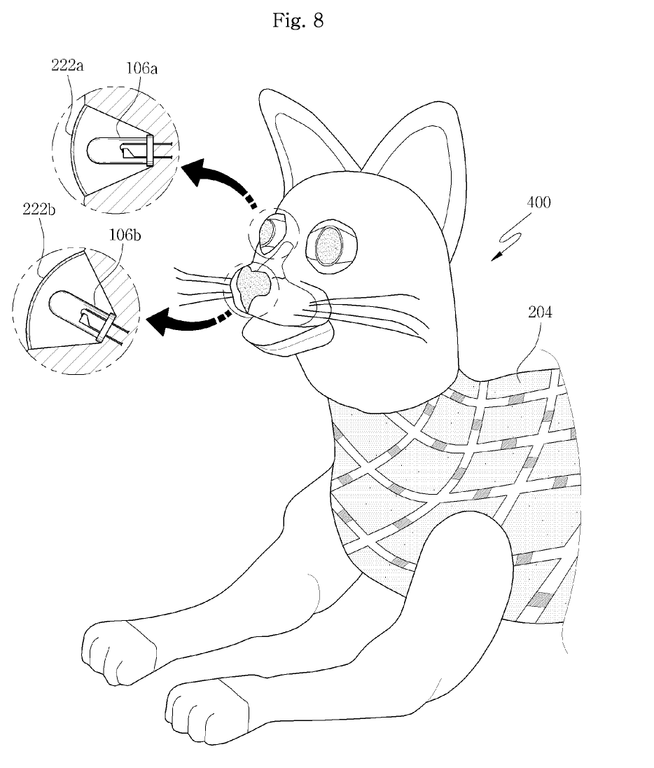

FIG. 8 illustrates a robot 400 having a brightness controllable robot eye and robot nose using a tactile sensor 204 according to an embodiment of the present invention. Referring to FIG. 8, the robot 400 includes LEDs 106a and 106b set inside the eyes and nose of the robot 400, the tactile sensor 204 covering the surface of the robot 400, and a controller (not shown) connected to the tactile sensor 204 and the LED lamps 106a and 106b to control the brightness of the LED lamps 106a and 106b.

The tactile sensor 204 attached to the body of the robot 400 senses the intensity of force or pressure applied to the robot body by a predetermined contact object and the controller (not shown) controls the brightness of the LED lamps 106a and 106b set in the eyes and nose of the robot 400 based on the sensed intensity. Lights from the LED lamps 106a and 106b are emitted through protection windows 222a and 222b, and thus brightness variation can be recognized.

The eyes and nose of the robot 400 are exemplary and the present invention can be applied to any part of the robot 400, which can include an LED set therein (For example, mouse, ear, cheek, tail, body, etc.). Furthermore, the tactile sensor 204 attached to the body of the robot 400 can be located at a specific part of the robot 400 or attached to the entire surface of the robot 400.

<Method of Controlling Brightness>

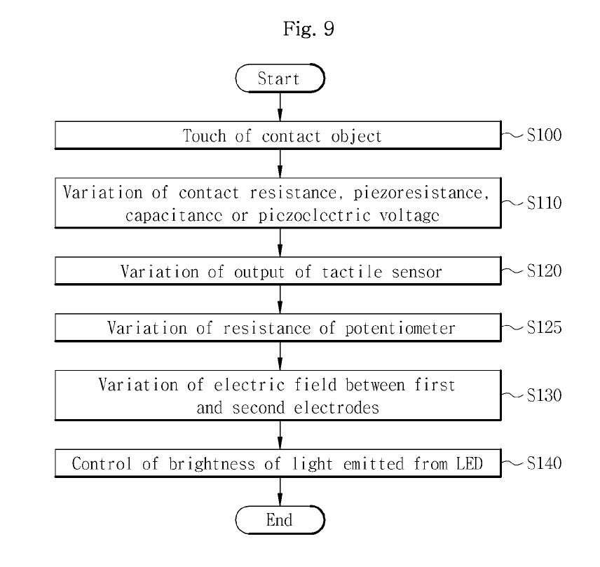

FIG. 9 is a flowchart showing a method of controlling the brightness of the brightness controllable LED illumination device according to an embodiment of the present invention. Referring to FIG. 9, when force or pressure is applied by a predetermined contact object (for example, a finger) in step S100, one of contact resistance of a tactile sensor, piezoresistance of a tactile sensor, capacitance of a tactile sensor and piezoelectric voltage of a tactile sensor is varied according to the intensity of the force or pressure applied by the predetermined contact object in step S110. The output of the tactile sensor is varied based on the variation in the contact resistance, piezoresistance, capacitance or piezoelectric voltage in step S120. The controller changes the resistance of a potentiometer based on the output signal of the tactile sensor in step S125.

Subsequently, the controller changes electric field between the first and second electrodes of the LED according to the variation in the resistance of the potentiometer based on the variation in the output of the tactile sensor in step S130. The brightness of the LED is controlled according to the electric field variation in step S140.

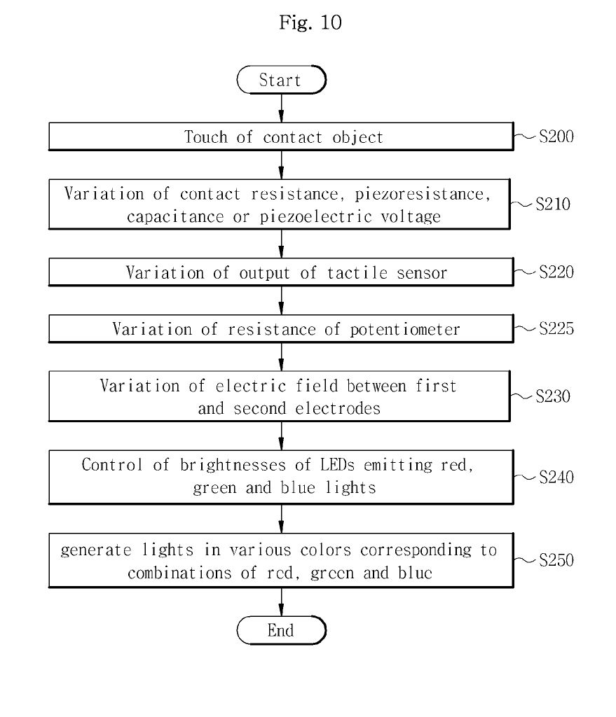

FIG. 10 is a flowchart showing a method of controlling brightnesses of LEDs respectively emitting red, green and blue lights to generate various colors according to an embodiment of the present invention. Referring to FIG. 10, when force or pressure is applied by a predetermined contact object in step S200, one of contact resistance of a tactile sensor, piezoresistance of a tactile sensor, capacitance of a tactile sensor and piezoelectric voltage of a tactile sensor is varied according to the intensity of the force or pressure applied by the predetermined contact object in step S210. The output of the tactile sensor is varied based on the variation in the contact resistance, piezoresistance, capacitance or piezoelectric voltage in step S220. The controller changes the resistance of a potentiometer based on the output signal of the tactile sensor in step S225. Subsequently, the controller changes electric field between the first and second electrodes of the LED according to the variation in the resistance of the potentiometer based on the variation in the output of the tactile sensor in step S230. The steps S200 through 5230 are identical to those of the method of brightness controlling method shown in FIG. 9.

The brightnesses of the LEDs respectively emitting red, green and blue lights are controlled in step S240. White light is obtained through the control of the brightnesses of the LEDs and various colors are generated according to combination of colors in step S250.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A brightness controllable LED illumination device with a tactile sensor sensing the intensity of force or the intensity of pressure, comprising:
at least one LED emitting light based on electric field formed between first and second electrodes;
a tactile sensor sensing the intensity of force or pressure applied by a predetermined contact object and generating an output signal corresponding to the sensed intensity; and
a controller connected to the tactile sensor and adjusting a variation in the electric field based on the output signal of the tactile sensor to control the brightness of the light emitted from the at least one LED.

2. The brightness controllable LED illumination device with a tactile sensor sensing the intensity of force or the intensity of pressure of claim 1, further comprising a display panel illuminated by the light emitted from the at least one LED.

3. The brightness controllable LED illumination device with a tactile sensor sensing the intensity of force or the intensity of pressure of claim 1, wherein each of the at least one LED generates a single light beam corresponding to one of red, green and blue, and the at least one LED corresponds to a plurality of LED groups each of which includes three LEDs.

4. The brightness controllable LED illumination device with a tactile sensor sensing the intensity of force or the intensity of pressure of claim 1, wherein each of the at least one LED generates a single light beam corresponding to one of complementary colors, and the at least one LED corresponds to a plurality of LED groups each of which includes two LEDs.

5. The brightness controllable LED illumination device with a tactile sensor sensing the intensity of force or the intensity of pressure of claim 1, wherein each of the at least one LED includes at least one phosphor.

6. The brightness controllable LED illumination device with a tactile sensor sensing the intensity of force or the intensity of pressure of claim 5, wherein each of the at least one LED emits blue light and the phosphor is yellow phosphor.

7. The brightness controllable LED illumination device with a tactile sensor sensing the intensity of force or the intensity of pressure of claim 1, wherein the output signal is proportional to the intensity of force or pressure applied by the contact object.

8. The brightness controllable LED illumination device with a tactile sensor sensing the intensity of force or the intensity of pressure of claim 1, wherein the tactile sensor uses contact resistance or piezoresistance.

9. The brightness controllable LED illumination device with a tactile sensor sensing the intensity of force or the intensity of pressure of claim 1, wherein the tactile sensor uses capacitance.

10. The brightness controllable LED illumination device with a tactile sensor sensing the intensity of force or the intensity of pressure of claim 1, wherein the tactile sensor is a piezoelectric tactile sensor.

11. The brightness controllable LED illumination device with a tactile sensor sensing the intensity of force or the intensity of pressure of claim 1, wherein the controller includes a potentiometer having resistance that is varied based on the output signal of the tactile sensor to control the electric field variation based on the resistance variation.

12. A plat panel display comprising the LED illumination device according to claim 1.

13. A mobile terminal keypad device comprising the LED illumination device according to claim 1.

14. A robot eye and nose comprising the LED illumination device according to claim 1.

15. A method of controlling the brightness of a brightness controllable LED illumination device with a tactile sensor sensing the intensity of force or the intensity of pressure, the method comprising:
a first variation step S110 in which one of contact resistance of a tactile sensor, piezoresistance of a tactile sensor, capacitance of a tactile sensor and piezoelectric voltage of a tactile sensor, which corresponds to the intensity of force or pressure applied by a predetermined contact object, is varied;
a second variation step S120 in which the output signal of the tactile sensor is varied based on the variation in the first variation step;
a third variation step S130 in which a controller varies electric field between first and second electrodes of an LED based on the output signal variation; and
a brightness control step S140 in which the brightness of light emitted from the LED is controlled based on the electric field variation.

16. The method of claim 15, further comprising a step S125 in which resistance of a potentiometer is varied based on the output signal of the tactile sensor between the second variation step S120 and the third variation step S130.

17. The method of claim 15, wherein the brightness control step S140 comprises the steps of:
controlling the brightnesses of lights emitted from LEDs emitting red, green and blue lights; and
controlling the brightnesses of the red, green and blue lights to generate light in a color corresponding to combination of red, green and blue.
